(19) United States
(12) Patent Application Publication
(10) Pub. No.: US 2011/0165756 A1
(43) Pub. Date: Jul. 7, 2011

(54) METHOD FOR MANUFACTURING SEMICONDUCTOR DEVICE

(75) Inventor: Satoru ISOGAI, Tokyo (JP)

(73) Assignee: Elpida Memory, Inc, Tokyo (JP)

(21) Appl. No.: 12/984,855

(22) Filed: Jan. 5, 2011

(30) Foreign Application Priority Data
Jan. 7, 2010 (JP) 2010-002076

(51) Int. Cl. H01L 21/02

(52) U.S. Cl. 438/397; 257/E21.019

(57) ABSTRACT

A semiconductor device includes a guard ring surrounding a memory cell region; a peripheral circuit region outside of the guard ring; a supporting film formed on the guard ring and on the peripheral circuit region; and a contact plug formed in the peripheral circuit region. The guard ring and the contact plug are completely filled with the same conductive material.

This application is based upon and claims the benefit of priority from Japanese Patent Application No. 2010-002076, filed on Jan. 7, 2010, the disclosure of which is incorporated herein in its entirety by reference.

### TECHNICAL FIELD

The invention relates to a method for manufacturing a semiconductor device.

### RELATED ART

Conventionally, a semiconductor device has been used, such as DRAM (Dynamic Random Access Memory) which comprises a memory cell region storing information, and a peripheral circuit region controlling writing the information into the memory cell region and reading the information from the memory cell region. In such a semiconductor device, a guard ring is formed to avoid cracks or peeling-off due to mechanical and/or thermal stresses in the memory cell region.

Japanese patent Laid-Open No.2000-196038 discloses the semiconductor device which includes a guard ring with an annular structure surrounding the memory cell region (claim 2, FIG. 5 to FIG. 9 or paragraphs [0035]to [0051]).

Japanese patent Laid-Open No.2004-111626 discloses the semiconductor device which includes a capacitor region, a peripheral region and a guard ring extended so as to space the capacitor region from the peripheral region (claims 4, 5, FIG. 35 or paragraphs [0064] to [0066]).

FIG. 13 to FIG. 15 illustrate a related method of manufacturing a semiconductor device. As shown in FIG. 13, after forming a transistor, contact plugs, interlayer insulating film 40a and supporting film 25 in a memory cell region, contact holes 41 and groove for guard ring 42 are simultaneously formed which all penetrate through interlayer insulating film 40a and supporting film 25.

Next, as shown in FIG. 14, first capacitor electrode material is formed so as to fill contact holes 41 and groove for guard ring 42 and cover supporting film 25. Then, using a CMP method, the first capacitor electrode material is polished away so that the first capacitor electrode material remains in contact holes 41 and groove for guard ring 42. At this time, contact holes 41 and groove for guard ring 42 are not completely filled with the first capacitor electrode material so that capacitor lower electrodes 28 and guard ring 43 with concave shapes are formed on the inner walls of contact holes 41 and groove for guard ring 42.

Subsequently, as shown in FIG. 15, openings 29 are formed in supporting film 25 using photolithography and dry etching techniques so as to expose portions of interlayer insulating film 40a in the memory cell region. Then, etchant is invaded into interlayer insulating film 40a through openings 29 to etch away interlayer insulating film 40, resulting in exposing outer walls of lower electrodes 28.

### SUMMARY OF THE INVENTION

In one embodiment, there is provided a method for manufacturing a semiconductor device, comprising:

providing a structure including a semiconductor substrate and an interlayer insulating film on the semiconductor substrate;

forming a groove for guard ring in the interlayer insulating film so as to surround a memory cell region of the structure, and forming a contact hole in the interlayer insulating film in a peripheral circuit region of the structure outside of the groove for guard ring;

filling the groove for guard ring and the contact hole with conductive material completely, to form a guard ring and a contact plug, respectively;

forming a supporting film on the guard ring and on the interlayer insulating film in the peripheral circuit region and the memory cell region;

forming a lower electrode in the interlayer insulating film and the supporting film in the memory cell region such that the lower electrode penetrates through the interlayer insulating film and the supporting film;

forming an opening in the supporting film in the memory cell region;

performing etching using the supporting film as a mask to remove the interlayer insulating film in the memory cell region; and

forming a capacitive insulating film and an upper electrode in this order on the lower electrode, to form a capacitor.

In another embodiment, there is provided a method for manufacturing a semiconductor device including a dynamic random access memory, comprising:

providing a structure including a semiconductor substrate, an interlayer insulating film on the semiconductor substrate, a MOS transistor on the semiconductor substrate, a bit line connected to a first impurity diffusion layer of the MOS transistor and positioned in the interlayer insulating film, and a pad connected to a second impurity diffusion layer of the MOS transistor and positioned in the interlayer insulating film;

forming a groove for guard ring in the interlayer insulating film so as to surround a memory cell region of the structure, and forming a contact hole in the interlayer insulating film in a peripheral circuit region of the structure outside of the groove for guard ring;

filling the groove for guard ring and the contact hole with conductive material completely, to form a guard ring and a contact plug, respectively;

forming a supporting film on the guard ring and on the interlayer insulating film in the peripheral circuit region and the memory cell region;

forming a lower electrode in the interlayer insulating film and the supporting film in the memory cell region such that the lower electrode penetrates through the interlayer insulating film and the supporting film, to be connected to the pad;

forming an opening in the supporting film in the memory cell region;

performing etching using the supporting film as a mask to remove the interlayer insulating film in the memory cell region; and

forming a capacitive insulating film and an upper electrode in this order on the lower electrode, to form a capacitor.

### BRIEF DESCRIPTION OF THE DRAWINGS

The above features and advantages of the present invention will be more apparent from the following description of certain preferred embodiments taken in conjunction with the accompanying drawings, in which:

FIG. 1 illustrates one process of an exemplary embodiment of a method for manufacturing a semiconductor device according to the invention;

FIG. 2 illustrates one process of an exemplary embodiment of a method for manufacturing a semiconductor device according to the invention;

FIG. 3 illustrates one process of an exemplary embodiment of a method for manufacturing a semiconductor device according to the invention;

FIG. 4 illustrates one process of an exemplary embodiment of a method for manufacturing a semiconductor device according to the invention;

FIG. 5 illustrates one process of an exemplary embodiment of a method for manufacturing a semiconductor device according to the invention;

FIG. 6 illustrates one process of an exemplary embodiment of a method for manufacturing a semiconductor device according to the invention;

FIG. 7 illustrates one process of an exemplary embodiment of a method for manufacturing a semiconductor device according to the invention;

FIG. 8 illustrates one process of an exemplary embodiment of a method for manufacturing a semiconductor device according to the invention;

FIG. 9 illustrates one process of an exemplary embodiment of a method for manufacturing a semiconductor device according to the invention;

FIG. 10 illustrates one process of an exemplary embodiment of a method for manufacturing a semiconductor device according to the invention;

FIG. 11 illustrates one process of an exemplary embodiment of a method for manufacturing a semiconductor device according to the invention;

FIG. 12 illustrates one process of an exemplary embodiment of a method for manufacturing a semiconductor device according to the invention;

FIG. 13 illustrates one process of a related method for manufacturing the semiconductor device;

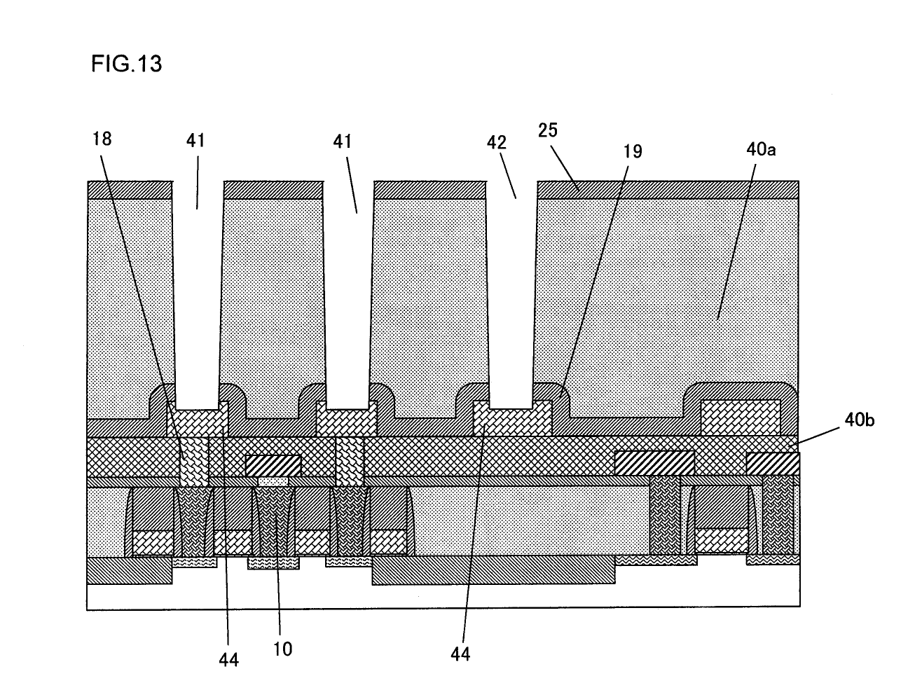

FIG. 14 illustrates one process of a related method for manufacturing the semiconductor device; and

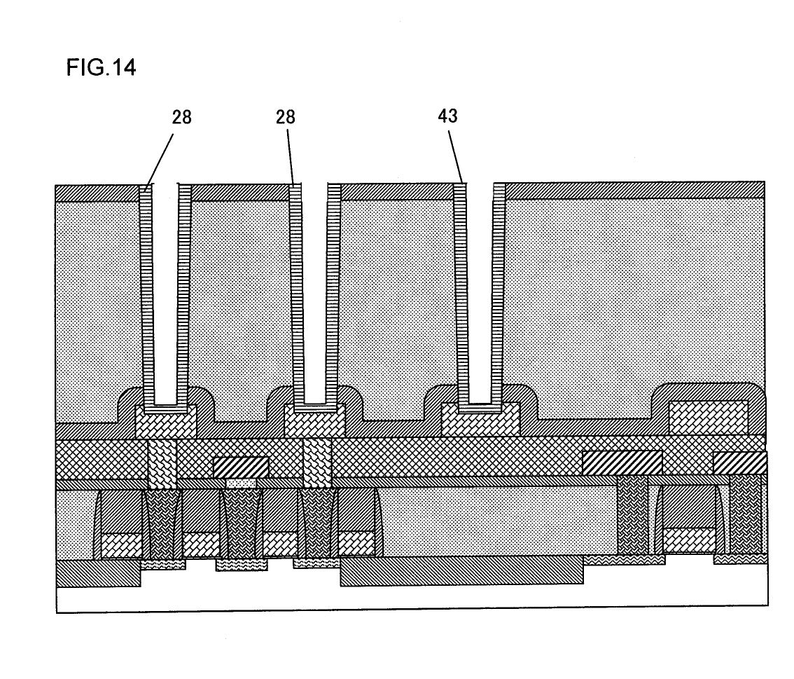

FIG. 15 illustrates one process of a related method for manufacturing the semiconductor device;

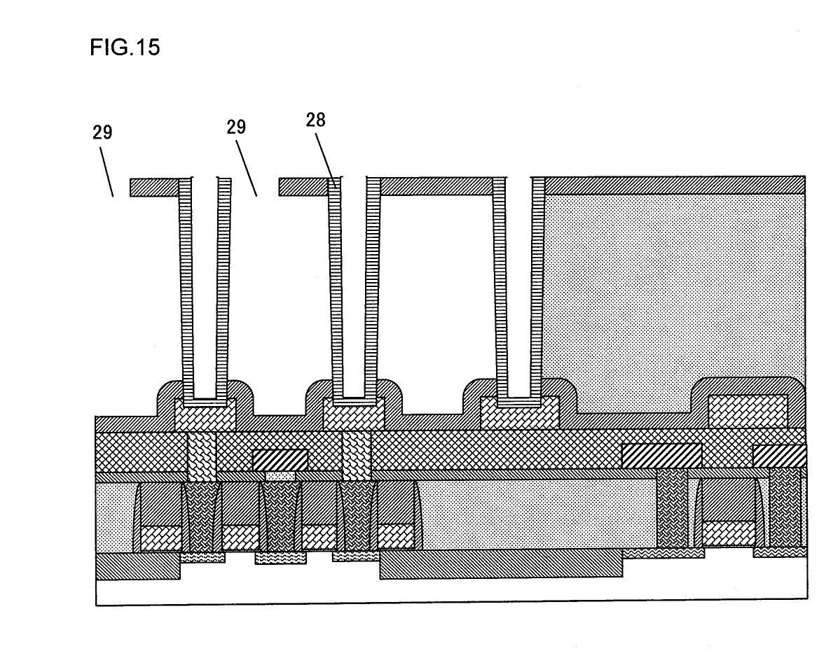

In the drawings, numerals have the following meanings. 1: semiconductor substrate, 2: isolation region, 3: device formation region, 4: gate insulating film, 5: gate electrode film, 6: mask insulating film, 7: cell source/drain regions, 8: side wall insulating film, 9: first interlayer insulating film, 10: cell contact plug, 11: second interlayer insulating film, 12: peripheral source/drain regions, 13: bit line contact plug, 14: contact plug, 15: bit line, 16: first interconnection, 17: third interlayer insulating film, 18: capacitor contact plug, 19: stopper insulating film, 20: fourth interlayer insulating film, 21a, 21b: first and second peripheral contact holes, 22: groove for guard ring, 23a: first peripheral contact plug, 23b: second peripheral contact plug, 24: guard ring, 25: supporting film, 26: memory cell contact hole, 28: lower electrode, 29: openings, 30: capacitive insulating film, 31: second capacitor electrode material or upper electrode, 33: fifth interlayer insulating film, 35:

second interconnection, 36: third peripheral contact plugs, a: capacitor pad, b: guard ring pad, c: contact pad, Lg: width of groove for guard ring, X: memory cell region, Y: peripheral circuit region, Z: guard ring formation region

### DETAILED DESCRIPTION OF EXEMPLARY EMBODIMENTS

The invention will be now described herein with reference to illustrative embodiments. Those skilled in the art will recognize that many alternative embodiments can be accomplished using the teachings of the present invention and that the invention is not limited to the embodiments illustrated for explanatory purpose.

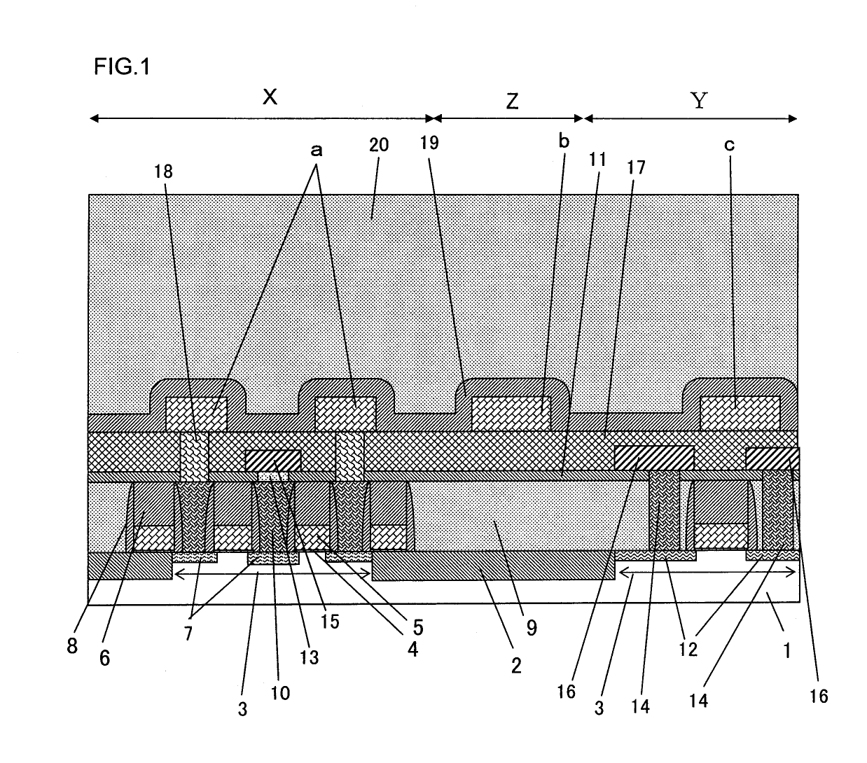

First, as shown in FIG. 1, isolation region 2 and device formation region 3 were formed in semiconductor substrate 1. In this exemplary embodiment, a silicon substrate was used as semiconductor substrate 1. Semiconductor substrate 1 is not limited to the silicon substrate, and may include a substrate made of germanium material, silicon germanium material, etc or a SOI substrate.

As described later, memory cell region X and peripheral circuit region Y around memory cell region X were formed in device formation region 3 of semiconductor substrate 1. A guard ring formation region Z as described later is disposed between memory cell region X and peripheral circuit region Y. In each of memory cell region X and peripheral circuit region Y, gate insulating film 4 was formed on semiconductor substrate 1, and gate electrode 5 was formed on gate insulating film 4, and mask insulating film 6 was formed on gate electrode 5. Then, by patterning those films, there was formed patterned gate electrode 5 on which patterned mask insulating film 6 was formed. Gate electrode 5 corresponds to a word line of the memory cell region.

Next, by performing ion-implantation, cell source and drain regions 7 and peripheral source and drain regions 12 were formed in a self-aligned manner with gate electrodes 5. Thereafter, side wall insulating films 8 were formed on side walls of gate electrodes 5. MOS transistor includes a portion of semiconductor substrate 1, gate insulating film 4, gate electrode 5 and source and drain regions 12.

First interlayer insulating film 9 was formed on an entire surface of the resultant structure. Contact holes were formed so as to penetrate through first interlayer insulating film 9 and then expose cell source and drain regions 7. Subsequently, by filling the contact holes with conductive material, cell contact plugs 10 were formed so as to be connected to cell source and drain regions 7. Herein, a phosphor-doped silicon film was employed as the conductive material. The conductive material may include refractory metals such as a titanium film, a titanium nitride film or a tungsten film.

Second interlayer insulating film 11 was formed on an entire surface of first interlayer insulating film 9. Next, contact hole was formed so that the contact hole penetrated through second interlayer insulating film 11 to expose cell contact plug 10. At the same time, contact holes were formed so that the contact holes penetrated through second and first interlayer insulating films 11, 9 to expose peripheral source and drain regions 12.

By filling the contact hole exposing the cell contact plug 10 with conductive material, bit line contact plug 13 was formed so as to be connected to cell contact plug 10. At the same time, by filling the contact holes exposing peripheral source and drain regions 12 with conductive material, contact plugs 14 were formed so as to be connected to peripheral source and drain regions 12.

Thereafter, there were formed bit line 15 connected to bit line contact plug 13 and first interconnections 16 connected to contact plugs 14 by patterning. At this time, thicknesses of bit line 15 and first interconnections 16 were 100 nm.

Third interlayer insulating film material was formed on bit line 15. This material was a plasma oxidized film whose thickness was 500 nm. By polishing third interlayer insulating film material with a CMP method, third interlayer insulating film 17 was formed which had thickness of 200 nm on bit line 15 and thickness of 300 nm on second interlayer insulating film 11.

Next, contact holes were formed so that contact holes penetrated through third and second interlayer insulating films 17, 11 to expose cell contact plugs 10. Then, by filling the contact holes with conductive material, capacitor contact plugs 18 were formed. Then, conductive material was formed onto an entire surface of the resultant structure, and, next, capacitor pads “a” connected to capacitor contact plugs 18 were formed using lithography and dry etching methods. At the same time, guard ring pad “b” and contact pad “c” were formed in the groove for guard ring formation region and the peripheral circuit region, respectively. Such pads a, b, c all had 100 nm of thicknesses.

Tungsten films were employed as materials of pads a, b, c. The materials of pads a, b, c are not limited to the tungsten films, and may include silicon films doped with impurities such as phosphor or arsenic, or refractory metal films such as a titanium nitride film or a stack of a titanium nitride film and a tungsten film.

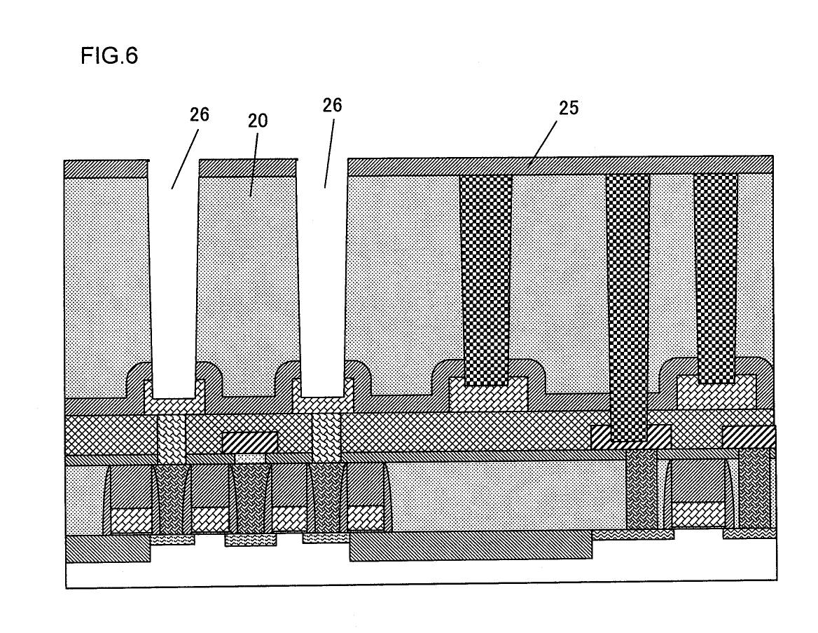

Subsequently, stopper insulting film 19 was formed on an entire surface including the surfaces of pads a, b, c. A silicon nitride film was used as the material of stopper insulating film 19. The material of stopper insulating film 19 is not limited to the silicon nitride film, and may include any film as long as it has etched rate lower than an etched rate of a fourth interlayer insulating film in an etching process of the fourth interlayer insulating film in FIG. 6 as will be described later. A thickness of stopper insulating film 19 was 100 nm.

Next, fourth interlayer insulating film 20 was formed on an entire surface of stopper insulating film 19. A BPSG film was used as material of fourth interlayer insulating film 20. The material of fourth interlayer insulating film 20 is not limited to the BPSG film, and may include a silicon oxide film such as a SOG film or a plasma oxidized film. Alternatively, a stack of such films may be used as the material of fourth interlayer insulating film 20. A thickness of fourth interlayer insulating film 20 was 2000 nm.

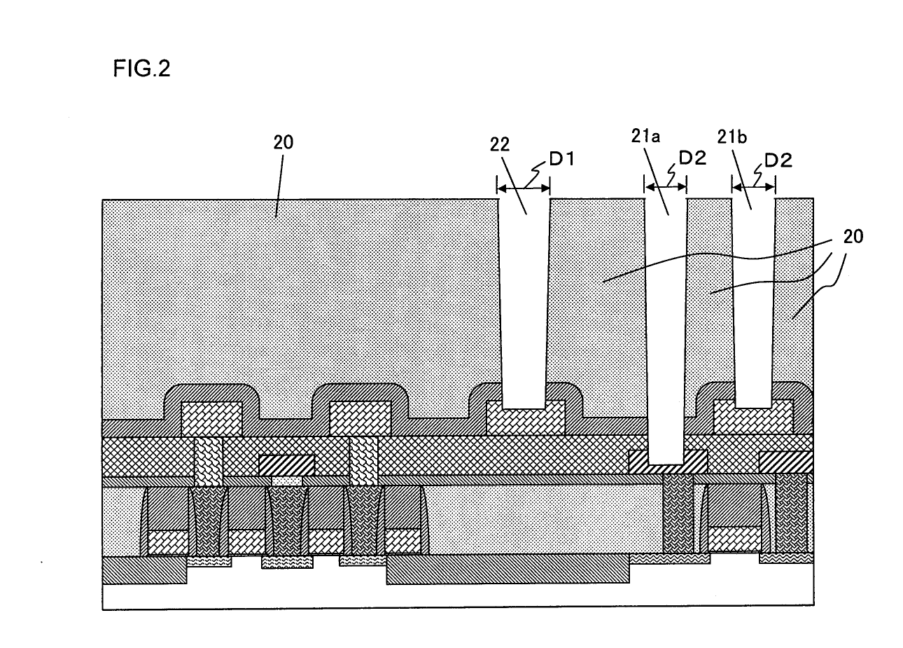

Then, as shown in a cross-sectional view of FIG. 2, using photolithography and dry etching methods, groove for guard ring 22 was formed so that groove for guard ring 22 penetrated through fourth interlayer insulating film 20 and stopper insulating film 19 to expose guard ring pad “b”. At the same time, second peripheral contact hole 21b was formed so that second peripheral contact hole 21b penetrated through fourth interlayer insulating film 20 and stopper insulating film 19 to expose contact pad “c”. At the same time, first peripheral contact hole 21a was formed so that first peripheral contact hole 21a penetrated through fourth interlayer insulating film 20, stopper insulating film 19, third interlayer insulating film 17 and a portion of first interconnection 16 to expose first interconnection 16. Hereinafter, the hole exposing contact pad “c” corresponds to second peripheral contact hole 21b, and the hole exposing first interconnection 16 corresponds to first peripheral contact hole 21a. Top diameters D2 (diameters of the uppermost portions) of first and second peripheral contact holes 21a, 21b were set to 200 nm, while width D1 of the groove for guard ring was set to 250 nm.

Here, in designing a mask, all of diameters D2 of first and second peripheral contact holes 21a, 21b and of width D1 of groove for guard ring 22 were equally set to 200 nm. However, groove for guard ring 22 with a groove shape pattern had higher exposure resolution than first and second peripheral contact holes 21a, 21b with hole shape patterns had. Accordingly, in forming a pattern using the photolithography technique, the pattern had been formed so that width D1 of the groove for guard ring became larger than diameters D2 of first and second peripheral contact holes 21a, 21b.

A depth of first peripheral contact hole 21 a was 2300 nm, and, thus, an aspect ratio thereof was high with about 12 of the aspect ratio.

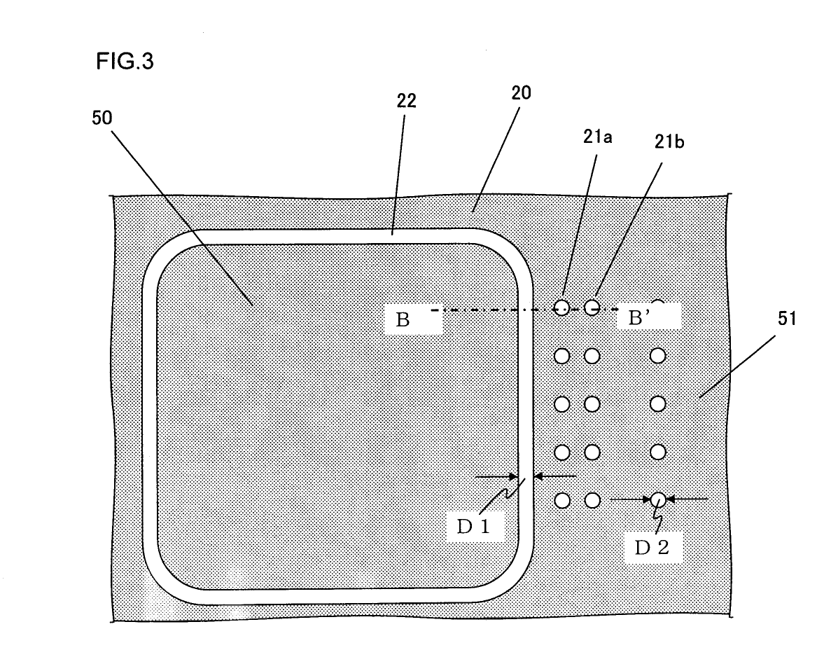

FIG. 3 is a top view illustrating a positional relationship between memory cell region 50 and peripheral circuit region 51. FIG. 1 and FIG. 2 correspond to cross-sectional views taken at a line B-B′ in FIG. 3. Region X in FIG. 1 corresponds to a portion of memory cell region 50 in FIG. 3, while Region Y in FIG. 1 corresponds to a portion of peripheral circuit region 51 in FIG. 3. In FIG. 3, groove for guard ring 22 with width D1 had an annular shape surrounding memory cell region 50. Although in FIG. 3, four corners of groove for guard ring 22 were rounded, in practice, they had a rectangular shape. An outer region of groove for guard ring 22 not surrounded with groove for guard ring 22 forms peripheral circuit region 51. First and second peripheral contact holes 21a, 21b with diameters D2 were disposed near groove for guard ring 22 and in the peripheral circuit region. Beneath groove for guard ring 22 with the annular shape, guard ring pad “b” as shown in FIG. 1 was formed so that the guard ring pad “b” has same annular shape as that of the groove for guard ring. Although in FIG. 3, first and second peripheral contact holes 21a, 21b were located, for example, at the right side of groove for guard ring 22, first and second peripheral contact holes 21a, 21b may be located at positions other than the right side of the groove.

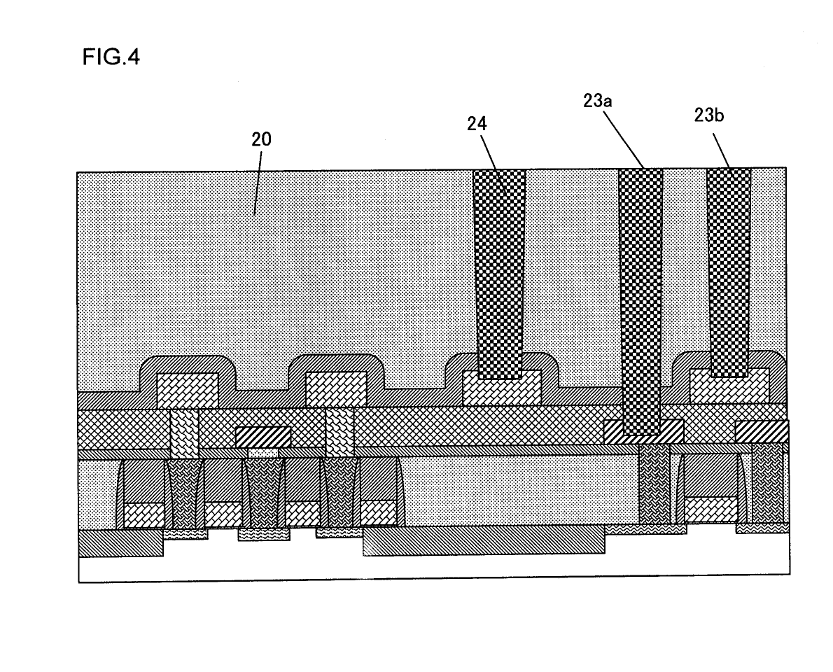

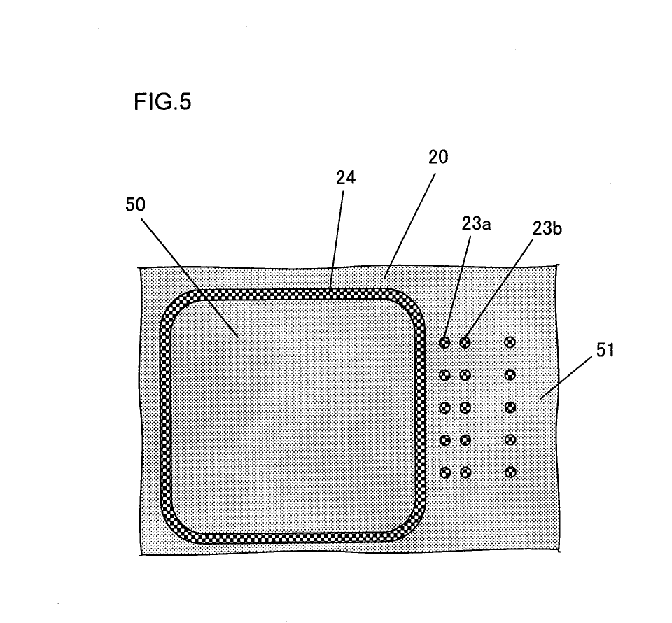

Here, FIG. 2 shows a cross-section while FIG. 3 is a top view including a portion corresponding to the cross-section of FIG. 2. The same holds for FIG. 4 and figures following FIG. 4, that is, FIGS. 5, 7 and 10 are top views including portions corresponding to the cross-sections of FIGS. 4, 6 and 9, respectively.

Next, as shown in FIG. 4 and FIG. 5, first and second peripheral contact holes 21a, 21b and groove for guard ring 22 were filled with first conductive film plug materials. A stack of a titanium nitride film and a tungsten film was used as the first conductive film plug materials. First, the titanium nitride film with 10 nm of a thickness was formed on entire surfaces of first and second peripheral contact holes 21a, 21b and groove for guard ring 22 so that first and second peripheral contact holes 21a, 21b and groove for guard ring 22 were not completely filled. Thereafter, the tungsten film with 190 nm of a thickness was formed so that first and second peripheral contact holes 21a, 21b and groove for guard ring 22 were completely filled. As mentioned above, width D1 of groove for guard ring 22 was 250 nm and top diameters D2 of first and second peripheral contact holes 21a, 21b were 200 nm, and, thus, the holes and groove were completely filled with the titanium nitride film having the 10 nm thickness and the tungsten film having the 190 nm thickness.

Then, the first conductive film plug material formed on fourth interlayer insulating film 20 was polished and removed by a CMP method, and, in turn, there were formed first and second peripheral contact plugs 23a, 23b and guard ring 24 made of the first conductive film plug material. In this process, instead of the CMP method, etching-back may be performed using dry etching. As a result, guard ring 24 with the annular shape had been formed so as to surround memory cell region 50. The width of guard ring 24 is defined by the width of the groove for guard ring, and it is preferable that the width of guard ring 24 is in a range of 100 to 300 nm. If the width of the groove for guard ring is smaller than 100 nm, the aspect ratio of the peripheral contact holes formed at the same time as in forming the groove may become higher, and, hence, there may occur a problem that the holes can not be fabricated so as to be opened. On the other hand, if the width of the groove for guard ring is larger than 300 nm, it may be difficult to fill the groove for guard ring completely, resulting in prevent a semiconductor chip area form reducing.

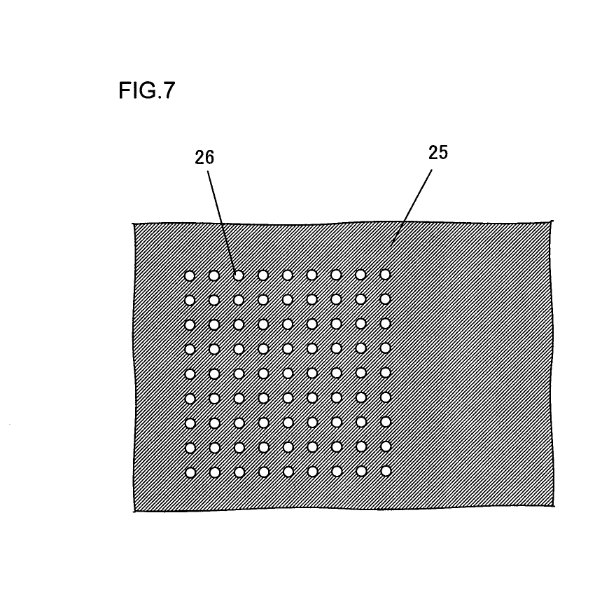

Thereafter, as shown in FIG. 6 and FIG. 7, capacitor holes 26 were formed in memory cell region 50.

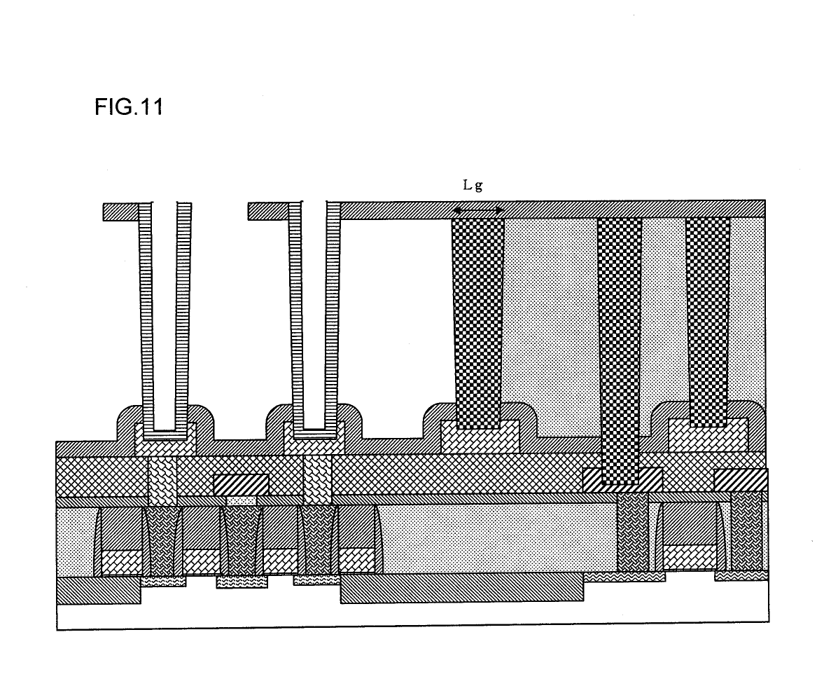

First, supporting film 25 was formed on an entire surface so as to cover fourth interlayer insulating film 20, guard ring 24, and first and second peripheral contact plugs 23a, 23b. A silicon nitride film with a thickness of 100 nm was used as supporting film 25. Although the silicon nitride film may be formed using various methods, it is preferable that a low pressure CVD method using dichlorosilane and ammonia as source gas or a HDP-CVD (high density plasma CVD) method using monosilane and ammonia as source gas is used because the film formed by such a method has a low etched rate. Different silicon and nitrogen source materials from each other may be used in each of such film forming methods. The material of supporting film 25 is not limited to the silicon nitride film, and may include any material as long as it has etched rate lower than an etched rate of fourth interlayer insulating film 20 in an etching process of the fourth interlayer insulating film 20 in FIG. 11 as will be described later. A thickness of supporting film 25 was 100 nm.

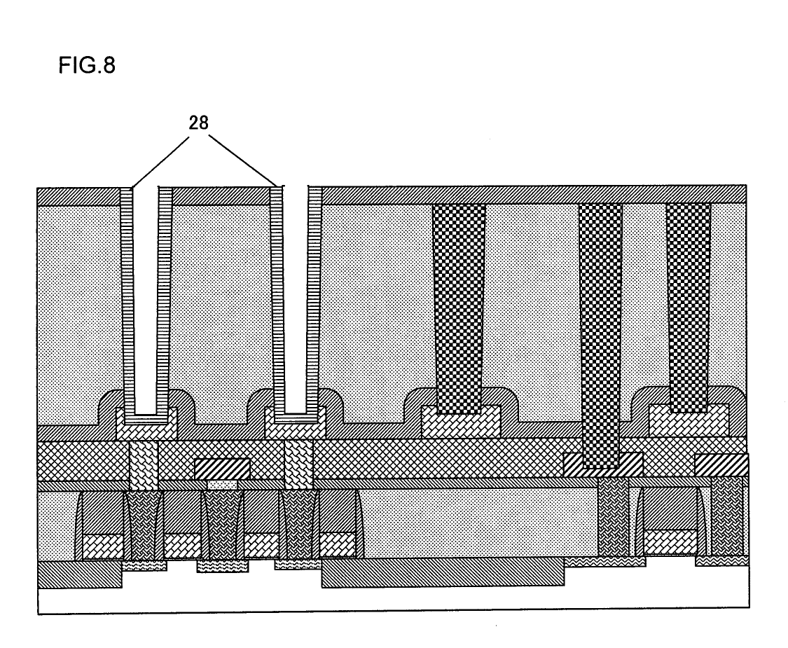

Next, using a lithography technique, a pattern made of a photoresist and having a plurality of holes arranged with regularity in memory cell region 50 was formed on supporting film 25 (the pattern is not shown in FIG. 8). Capacitor holes 26 were formed by performing anisotropic dry etching using the patterned photoresist as a mask so that the capacitor holes 26 penetrated through supporting film 25, fourth interlayer insulating film 20 and stopper insulating film 19 to expose capacitor pads a. Top diameters (diameters of the uppermost portions) of capacitor holes 26 was 150 nm. The depths of capacitor holes 26 was about 2000 nm, and, thus, the aspect ratio thereof was about 13, thereby producing the capacitor holes with the high aspect ratio. Although the photoresist was used as the mask in the anisotropic dry etching, it also is possible that an amorphous silicon film or a silicon film is formed as a hard mask beneath the photoresist, and, then, the mask pattern in the photoresist is transferred to the hard mask by dry etching, and, next, supporting film 25, fourth interlayer insulating film 20 and stopper insulating film 19 are subjected to the anisotropic dry etching using the hard mask. Using the latter method, capacitor holes 26 with high precision may be formed.

Subsequently, as shown in FIG. 8, after removing the photoresist, first capacitor electrode material was formed so as to fill capacitor holes 26 and cover supporting film 25. A film thickness of the first capacitor electrode materials was 30 nm which did not completely fill capacitor holes 26. A titanium nitride film was used as the first capacitor electrode material. The first capacitor electrode material is not limited to the titanium nitride film, and a silicon film doped with impurities such as phosphor or arsenic, or a refractory metal film such as a tungsten film or a ruthenium (Ru) film.

Then, using a CMP method, the first capacitor electrode material was polished away, so that the top surface of supporting film 25 was exposed and the first capacitor electrode material remained in capacitor holes 26 so as to extend along the inner walls of capacitor holes 26. In this way, capacitor lower electrodes 28 with concave cross-sectional shapes were formed. The method of forming capacitor lower electrodes 28 is not limited to the CMP method, and a dry etching method may be used in forming capacitor lower electrodes 28.

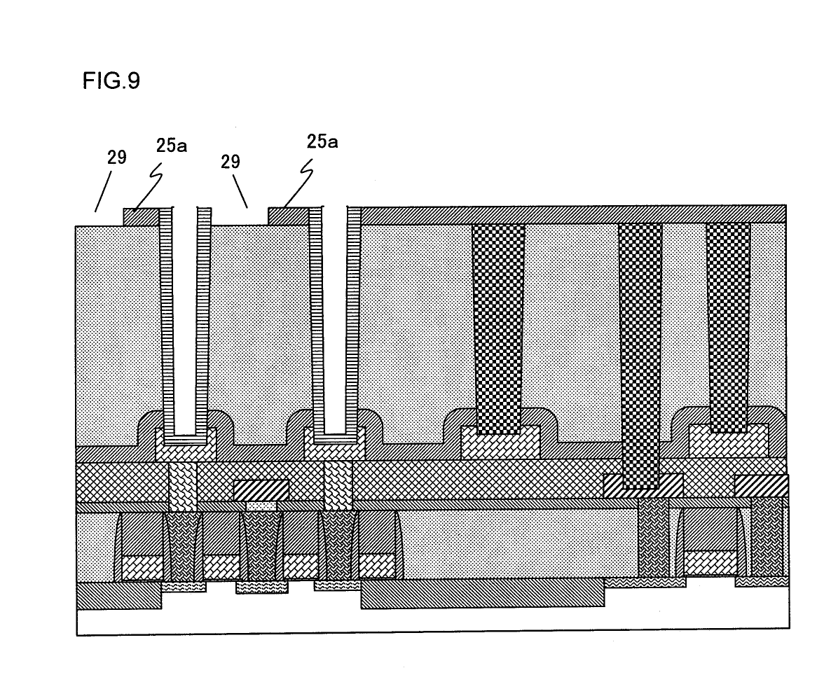

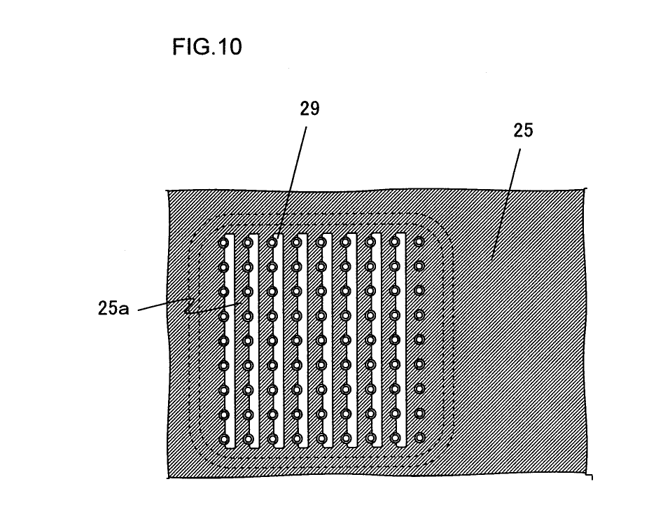

Next, as shown in FIG. 9 and FIG. 10, openings 29 were formed in supporting film 25 using photolithography and dry etching techniques so as to expose portions of fourth interlayer insulating film 20 in memory cell region 50 (hereinafter, openings 29 may be referred to as “supporting film openings”). Supporting body film openings 29 serve as invading openings through which the etchant invades fourth interlayer insulating film 20 to etch away fourth interlayer insulating film 20 in a process of FIG. 11 as described later. Remaining portions of supporting film 25 contacted with the outer side surfaces of lower electrodes 28. Remaining portions of supporting film 25 serve as beam 25a for supporting lower electrodes 28 so that lower electrodes 28 are prevented from falling down. The dotted line in FIG. 10 shows the region where the guard ring was formed. As shown in FIG. 10, beam 25a in memory cell region 50 interconnected lower electrodes 28 with each other, and also contacted with supporting film 25 formed in an outer region of memory cell region 50, namely, in peripheral circuit region 51. Each of all of lower electrodes 28 partly contacted with beam 25a. Furthermore, beam 25a contacted with supporting film 25 formed with large area in the outer region of memory cell region 50, namely, in peripheral circuit region 51. Therefore, mechanical strength thereof can be sustained, resulting in sustaining mechanical strength of lower electrodes 28 contacted with beam 25a.

Although as shown in FIG. 10, supporting film openings 29 were formed as an elongate shape extending in a column direction, the configuration of supporting film openings 29 is not limited thereto, and supporting film openings 29 may be formed as an elongate shape extending in a row direction or in a slant direction. Moreover, it is not necessary to expose completely the outer side surface of each of all of lower electrodes 28, and supporting film openings 29 may be formed so that it has openings pattern with isolated ellipse shape openings and does not expose the outer side surfaces of all of lower electrodes 28.

Then, as shown in FIG. 11, by making the etchant invade fourth interlayer insulating film 20 through supporting film openings 29, fourth interlayer insulating film 20 was etched away. Herein, solution at least containing hydrofluoric acid was used as the etchant, and the etching using wet etching was performed (hereinafter, this etching may be referred to as “fourth interlayer insulating film removal etching”). By this etching, stopper insulating film 19 and outer walls of lower electrodes 28 were exposed. In this etching, beam 25a contacting with outer side surfaces of the upper portions of lower electrodes 28 remained. If beam 25a does not exist, the supporting body for supporting lower electrodes 28 does not exist after the fourth interlayer insulating film removal etching, so that lower electrodes 28 may collapse due to surface tension resulting from cleaning process with pure water after the etching. However, in this exemplary embodiment, since beam 25a remained, and, lower electrodes 28 were prevented from collapsing after the fourth interlayer insulating film removal etching. Moreover, in the fourth interlayer insulating film removal etching, guard ring 24 formed at the boundary between memory cell region 50 and peripheral circuit region 51 functions as a wall for suppressing etchant invasion. That is to say, since guard ring 24 functions as the wall for preventing the etchant from invading in peripheral circuit region 51, the etchant for removing fourth interlayer insulating film 20 in memory cell region 50 can not invade peripheral circuit region 51. Accordingly, the side wall of fourth interlayer insulating film 20 in peripheral circuit region 51 is not etched away. Moreover, since supporting film 25 covers the top surface of guard ring 24 and the top surface of fourth interlayer insulating film 20 in peripheral circuit region 51, etching is prevented from occurring from the top surface of fourth interlayer insulating film 20 in peripheral circuit region 51.

Guard ring 24 was formed as the structure completely filled with the first conductive film plug material. In this exemplary embodiment, width Lg of the aperture of groove for guard ring 22 was set to approximately 250 nm, and this width corresponds to width of guard ring 24. In this way, guard ring 24 was formed with the thick conductive film. Further, since the supporting film was formed on the top surface of the guard ring, the width of the guard ring, namely, the width Lg of aperture of the groove for guard ring substantially corresponded to a contact length between the guard ring and the supporting film.

In this exemplary embodiment, the contact length was 250 nm. Moreover, the contact length may be adjusted to an arbitrary length by adjusting the width of the guard ring. As a result, in the exemplary embodiment, the contact length between the guard ring and the supporting film 25 can be increased, abnormal etching can be effectively avoided in which the etchant penetrates through between the guard ring and the supporting film 25, and, then, etches away the peripheral circuit region so as to form cavities in the peripheral circuit region during the fourth interlayer insulating film removal etching.

Furthermore, since guard ring 24 was formed as the structure completely filled with the first conductive film plug material, the guard ring can prevent the etchant from invading the peripheral circuit region. The mechanical strength of the guard ring can increase. Consequently, the guard ring can be prevented from being deformed and destroyed due to the liquid pressure of chemical solutions or the wind pressure in drying process during the fourth interlayer insulating film removal etching or in the cleaning process after the fourth interlayer insulating film removal etching.

In this exemplary embodiment, as shown in FIG. 9 to FIG. 11, supporting film 25 covered the top surface of guard ring 24, the top surface of fourth interlayer insulating film 20 in peripheral circuit region 51 outside of guard ring 24, and the top surfaces of first and second peripheral contact plugs 23a, 23b. Moreover, supporting film became supporting portions 25a for interconnecting a plurality of the capacitor lower electrodes with each other in the memory cell region. In other words, the supporting film 25 covering the top surface of guard ring 24, the top surface of fourth interlayer insulating film 20 in peripheral circuit region 51 outside of guard ring 24, and the top surfaces of first and second peripheral contact plugs 23a, 23b and beam 25a for interconnecting a plurality of the capacitor lower electrodes with each other in the memory cell region belonged to the same supporting film.

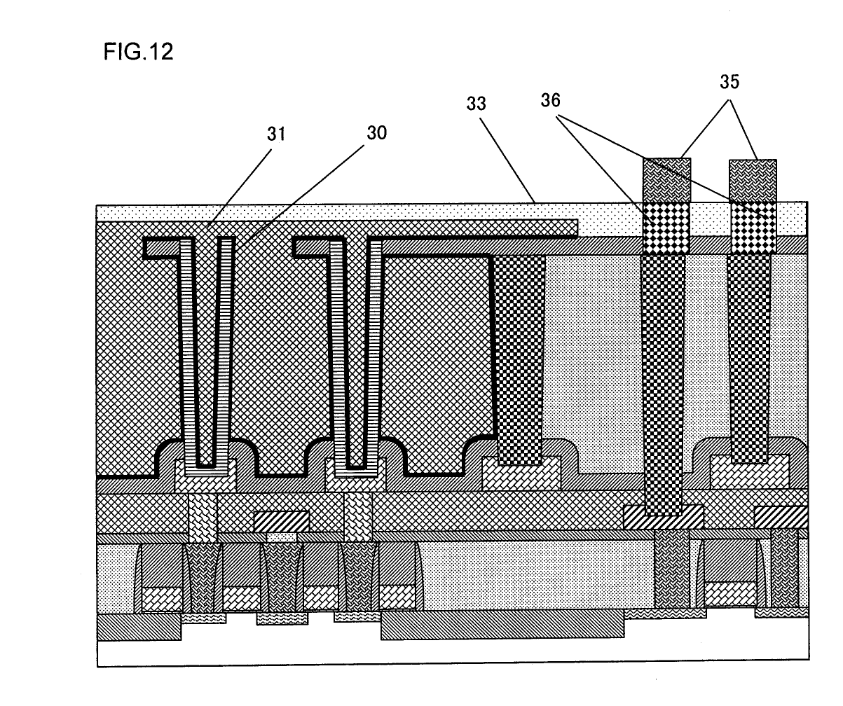

Next, as shown in FIG. 12, capacitive insulating film 30 was formed on the entire surface of the memory cell region. A tantalum oxide film was used as the material of capacitive insulating film 30. The material of capacitive insulating film 30 is not limited thereto, and alumina, a hafnium oxide film or a zirconium oxide film may be used as the material of capacitive insulating film 30.

Second capacitor electrode material to be upper electrodes was formed on the entire surface of the resultant structure. A stack of a titanium nitride film and a tungsten film was used as second capacitor electrode material 31. Second capacitor electrode material 31 is not limited thereto, and a doped silicon film or a stack of a titanium nitride film and a doped silicon film may be used as second capacitor electrode material 31. Film thickness of second capacitor electrode material 31 was set to 100 nm.

Upper electrodes 31 were formed by patterning second capacitor electrode material 31 using lithography and dry etching techniques. At this time, supporting film 25 was exposed by removing second capacitor electrode material 31 on the first and second peripheral contact plugs 23a, 23b.

Fifth interlayer insulating film material was formed on the entire surface of the resultant structure. Using a plasma CVD method, a silicon oxide film with 600 nm of a thickness was formed as the fifth interlayer insulating film material. Using a CMP method, the fifth interlayer insulating film material was polished and thus planarized so that fifth interlayer insulating film 33 was formed. The thickness of fifth interlayer insulating film 33 on the supporting film was 400 nm, while the thickness of fifth interlayer insulating film 33 on the second capacitor electrode was 300 nm.

Third peripheral contact holes with depth of 500 nm were formed so that the third peripheral contact holes penetrated through fifth interlayer insulating film 33 and supporting film 25 to expose the top surfaces of first and second peripheral contact plugs 23a, 23b. The top diameter (diameters of the uppermost portion) of the third peripheral contact holes was 200 nm which was the same as those of first and second peripheral contact plugs 23a, 23b. Since aspect ratio of the third peripheral contact holes was 2 to 3 and low, the third peripheral contact holes can be easily formed using the dry etching technique. Accordingly, it is not necessary to employ an expensive etching apparatus with high performance.

Third peripheral contact holes were filled with the second conductive film plug material to form the third peripheral contact plugs. A stack of a titanium nitride film and a tungsten film was used as the second conductive film plug material. Since aspect ratio of the third peripheral contact holes was low as mentioned above, it is easy to fill the third peripheral contact holes with metal material. As a result, it is possible to form the barrier metal using a sputtering method with low cost. Second interconnections 35 connected to third peripheral contact plugs 36 were formed.

Using the above described process, the semiconductor device had been completed. In this exemplary embodiment, the guard ring had the structure in which the groove for guard ring was fully filled with the conductive material. Accordingly, as mentioned above, abnormal etching is effectively avoided in which the etchant penetrates through the guard ring, and etches away the interlayer insulating film in the peripheral circuit region during the fourth interlayer insulating film removal etching. Furthermore, the guard ring can be prevented from being deformed or being peeled off due to the liquid pressure of chemical solutions or the wind pressure in etching process or the cleaning process.

In the manufacturing method according to this exemplary embodiment, since the forming of the peripheral contact plugs occurred at the same time as the forming of the guard ring, and, hence, it is possible to form the guard ring fully filled with the conductive material without adding complex processes of forming the contact holes with high aspect ratios using the etching and then filling the etched contact holes with the conductive material. Consequently, it is possible to form the guard ring fully filled with the conductive material without considerable rise of the manufacturing cost.

It is apparent that the present invention is not limited to the above embodiments, but may be modified and changed without departing from the scope and spirit of the invention.

In addition, while not specifically claimed in the claim section, the applications reserve the right to include in the claim section at any appropriate time the following semiconductor devices:

1. A semiconductor device, comprising:

a memory cell region including a capacitor;

a guard ring surrounding the memory cell region;

a peripheral circuit region outside of the guard ring and including an interlayer insulating film;

a supporting film formed on the guard ring and on at least one portion of the interlayer insulating film in the peripheral circuit region, the supporting film contacting with an outer side surface of the capacitor in the memory cell region; and

a contact plug formed in the peripheral circuit region,

wherein the guard ring and the contact plug are filled with same conductive material.

2. The semiconductor device according to the above 1,

wherein the memory cell region comprises:

a transistor; and

a bit line connected to one of a source region and a drain region of the transistor,

wherein the capacitor comprises a lower electrode with a concave shape, a capacitive insulating film, and an upper electrode in this order, and

the capacitor is connected to the other of the source region and the drain region of the transistor, and

wherein the semiconductor device is Dynamic Random Access Memory.

3. The semiconductor device according to the above 1,
wherein a width of the guard ring is 100 to 300 nm.
4. The semiconductor device according to the above 1, wherein the conductive material is a stack of a titanium nitride film and a tungsten film.
5. A semiconductor device, comprising:

a plurality of capacitors;

a guard ring surrounding the plurality of the capacitors;

a supporting film formed on the guard ring such that the supporting film contacts with outer side surfaces of the plurality of the capacitors; and

a contact plug outside of the guard ring,

wherein the guard ring and the contact plug are completely filled with same conductive material.

6. The semiconductor device according to the above 5, further comprising:

a plurality of transistors; and

a bit line connected to one of a source region and a drain region of each of the transistors;

wherein each of the capacitors comprises a lower electrode with a concave shape, a capacitive insulating film, and an upper electrode in this order, and

each of the capacitor is connected to the other of the source region and the drain region of each of the transistors; and

wherein the semiconductor device is Dynamic Random Access Memory.

7. The semiconductor device according to the above 5, wherein a width of the guard ring is 100 to 300 nm.
8. The semiconductor device according to the above 5, wherein the conductive material is a stack of a titanium nitride film and a tungsten film.

What is claimed is:

1. A method for manufacturing a semiconductor device, comprising:
providing a structure including a semiconductor substrate and an interlayer insulating film on the semiconductor substrate;
forming a groove for guard ring in the interlayer insulating film so as to surround a memory cell region of the structure, and forming a contact hole in the interlayer insulating film in a peripheral circuit region of the structure outside of the groove for guard ring;
filling the groove for guard ring and the contact hole with conductive material completely, to form a guard ring and a contact plug, respectively;
forming a supporting film on the guard ring and on the interlayer insulating film in the peripheral circuit region and the memory cell region;
forming a lower electrode in the interlayer insulating film and the supporting film in the memory cell region such that the lower electrode penetrates through the interlayer insulating film and the supporting film;
forming an opening in the supporting film in the memory cell region;
performing etching using the supporting film as a mask to remove the interlayer insulating film in the memory cell region; and
forming a capacitive insulating film and an upper electrode in this order on the lower electrode, to form a capacitor.

2. The method for manufacturing a semiconductor device according to claim 1,
wherein a width of the guard ring is 100 to 300 nm.

3. The method for manufacturing a semiconductor device according to claim 1,
wherein in filling the groove for guard ring and the contact hole with conductive material, the guard ring and the contact plug made of a stack of a titanium nitride film and a tungsten film are formed.

4. The method for manufacturing a semiconductor device according to claim 1,
wherein the supporting film is a silicon nitride film.

5. The method for manufacturing a semiconductor device according to claim 1,
wherein in forming the supporting film, the silicon nitride film is formed as the supporting film by a low pressure CVD method using dichlorosilane and ammonia as source gas or a high density plasma CVD method using monosilane and ammonia as source gas.

6. The method for manufacturing a semiconductor device according to claim 1,
wherein in forming the lower electrode, a plurality of the lower electrodes are formed, and
in forming the opening, the opening is formed in the supporting film so that the supporting film remains in contact with at least portions of outer sidewalls of the lower electrodes adjacent to each other.

7. The method for manufacturing a semiconductor device according to claim 1,
wherein in performing etching using the supporting film as the mask, the interlayer insulating film is removed by wet etching using an etchant containing hydrofluoric acid.

8. A method for manufacturing a semiconductor device including a dynamic random access memory, comprising:
providing a structure including a semiconductor substrate, an interlayer insulating film on the semiconductor substrate, a MOS transistor on the semiconductor substrate, a bit line connected to a first impurity diffusion layer of the MOS transistor and positioned in the interlayer insulating film, and a pad connected to a second impurity diffusion layer of the MOS transistor and positioned in the interlayer insulating film;
forming a groove for guard ring in the interlayer insulating film so as to surround a memory cell region of the structure, and forming a contact hole in the interlayer insulating film in a peripheral circuit region of the structure outside of the groove for guard ring;
filling the groove for guard ring and the contact hole with conductive material completely, to form a guard ring and a contact plug, respectively;
forming a supporting film on the guard ring and on the interlayer insulating film in the peripheral circuit region and the memory cell region;
forming a lower electrode in the interlayer insulating film and the supporting film in the memory cell region such that the lower electrode penetrates through the interlayer insulating film and the supporting film, to be connected to the pad;
forming an opening in the supporting film in the memory cell region;
performing etching using the supporting film as a mask to remove the interlayer insulating film in the memory cell region; and
forming a capacitive insulating film and an upper electrode in this order on the lower electrode, to form a capacitor.

9. The method for manufacturing a semiconductor device according to claim 8,
wherein a width of the guard ring is 100 to 300 nm.

10. The method for manufacturing a semiconductor device according to claim 8,
wherein in filling the groove for guard ring and the contact hole with conductive material, the guard ring and the contact plug made of a stack of a titanium nitride film and a tungsten film are formed.

11. The method for manufacturing a semiconductor device according to claim 8,
wherein the supporting film is a silicon nitride film.

12. The method for manufacturing a semiconductor device according to claim 8,
wherein in forming the supporting film, the silicon nitride film is formed as the supporting film by a low pressure CVD method using dichlorosilane and ammonia as source gas or a high density plasma CVD method using monosilane and ammonia as source gas.

13. The method for manufacturing a semiconductor device according to claim 8,
wherein in forming the lower electrode, a plurality of the lower electrodes are formed, and
in forming the opening, the opening is formed in the supporting film so that the supporting film remains in contact with at least portions of outer sidewalls of the lower electrodes adjacent to each other.

14. The method for manufacturing a semiconductor device according to claim 8,
wherein in performing etching using the supporting film as the mask, the interlayer insulating film is removed by wet etching using an etchant containing hydrofluoric acid.
